(19) United States
(12) Patent Application Publication
(10) Pub. No.: US 2023/0126847 A1
(43) Pub. Date: Apr. 27, 2023

(54) LENS MODULE AND ELECTRONIC DEVICE HAVING THE LENS MODULE

(71) Applicant: TRIPLE WIN TECHNOLOGY(SHENZHEN) CO.LTD., Shenzhen (CN)

(72) Inventors: JIAN-CHAO SONG, Shenzhen (CN); JING-WEI LI, Shenzhen (CN); SHIN-WEN CHEN, New Taipei (TW); YU-SHUAI LI, Shenzhen (CN)

(21) Appl. No.: 17/562,303

(22) Filed: Dec. 27, 2021

(30) Foreign Application Priority Data
Oct. 27, 2021 (CN) 202111257958.5

(51) Int. Cl. H04N 5/225; H05K 1/18

(52) U.S. Cl. CPC H04N 5/2253; H04N 5/2254; H05K 1/181; H05K 2201/10151; H05K 2201/10121

(57) ABSTRACT

A lens module includes a circuit board and a photosensitive chip. The first rigid portion includes a first through hole. The lens module further includes a metal board. The metal board includes a metal body and a convex box located on one of the surfaces of the metal body. The circuit board is mounted on a surface of the metal board. The convex box is received in the first through hole. The photosensitive chip is mounted on the convex box. The disclosure also provides an electronic device having the lens module.

### FIELD

The subject matter herein generally relates to imaging, to a lens module and an electronic device having the lens module.

### BACKGROUND

Electronic devices, such as mobile phones or tablet computers, may have lens module. Such a lens module may include a circuit board, a photosensitive chip mounted on the circuit board, and a lens disposed above and facing the photosensitive chip. When the electronic device becomes smaller, a distance between the lower surface of the lens and the upper surface of the photosensitive chip (that is, a back focal length of the lens) needs to be reduced. However, the back focal length of the existing lens modules may be large, thereby affecting a height of the lens module, and miniaturization is problematic.

### BRIEF DESCRIPTION OF THE DRAWINGS

Implementations of the present disclosure will now be described, by way of embodiments, with reference to the attached figures.

FIG. 1 is a diagrammatic view of an embodiment of a lens module according to the present disclosure.

FIG. 2 is an exploded, diagrammatic view of the lens module of FIG. 1.

FIG. 3 is an exploded, diagrammatic view of the lens module of FIG. 1, from another angle.

FIG. 4 is a cross-sectional view taken along IV-IV line of FIG. 1.

FIG. 5 is a diagrammatic view of an embodiment of an electronic device having the lens module of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

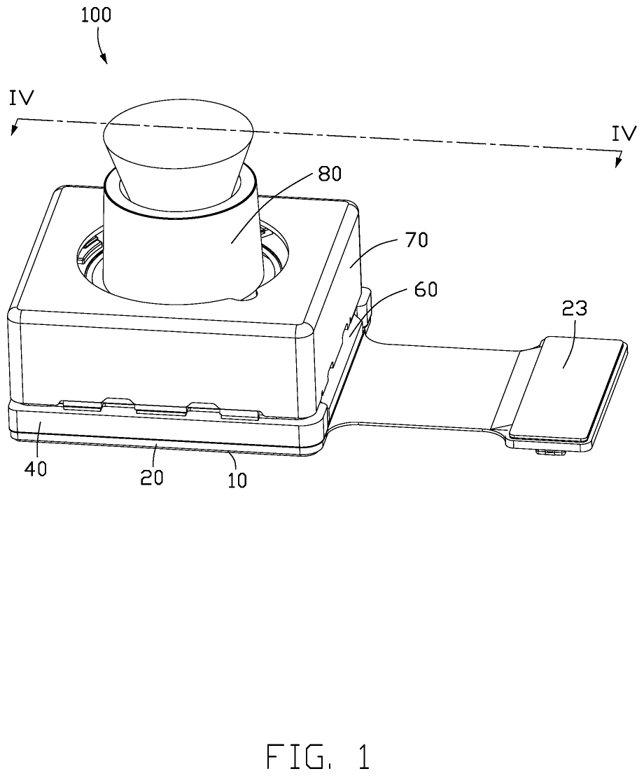

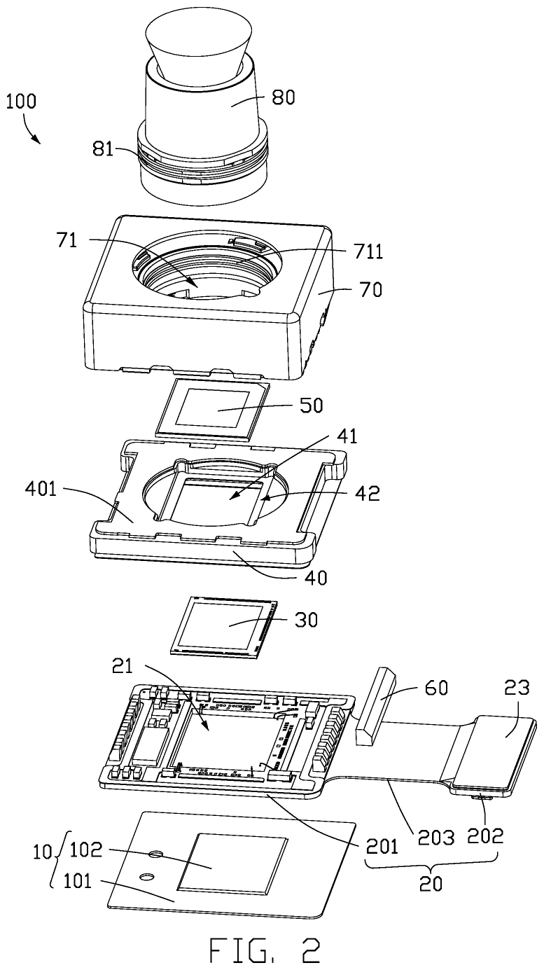

FIGS. 1 and 2 illustrate an embodiment of a lens module 100. The lens module 100 includes a metal board 10, a circuit board 20, a photosensitive chip 30, a base 40, an optical filter 50, an adhesive layer 60, a voice coil motor 70, and a lens 80.

In at least one embodiment, the metal board 10 includes a metal body 101 and a convex box 102 located on a surface of the metal body 101. The convex box 102 protrudes outwards from a portion of surface of the metal body 101. In at least one embodiment, the metal board 10 may be rectangular. In at least one embodiment, the metal board 10 is made of steel.

In at least one embodiment, the circuit board 20 may be a flexible circuit board, a rigid circuit board, or a rigid-flexible circuit board. In an embodiment, the circuit board 20 is a rigid-flexible circuit board, including a first rigid portion 201, a second rigid portion 202, and a flexible portion 203 between the first rigid portion 201 and the second rigid portion 202.

The first rigid portion 201 includes a first through hole 21 passing through the first rigid portion 201. The first rigid portion 201 is mounted on the surface of the metal board 10, and the convex box 102 is received in the first through hole 21. A plurality of electronic components 22 are mounted on the first rigid portion 201. The electronic components 22 may be at least one of resistors, capacitors, diodes, triodes, relays, and electrically erasable programmable read-only memory (EEPROM).

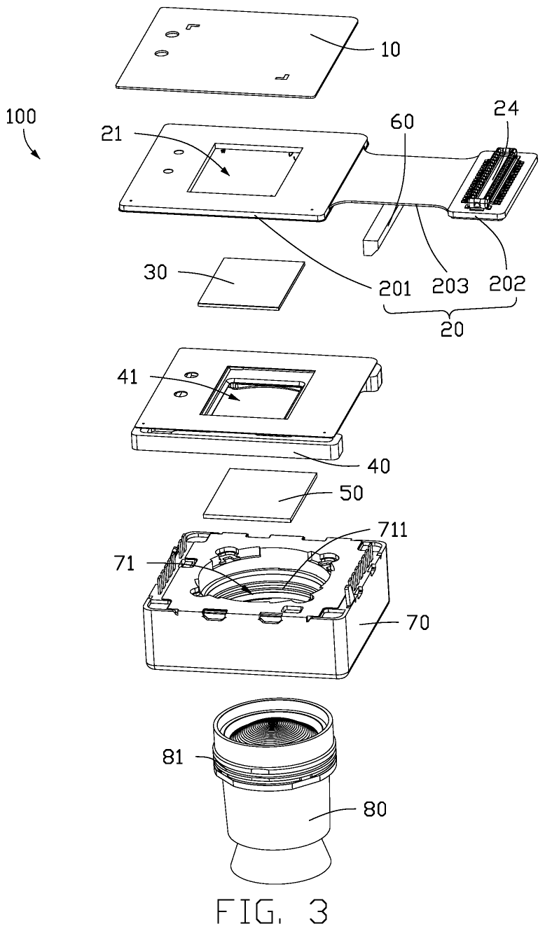

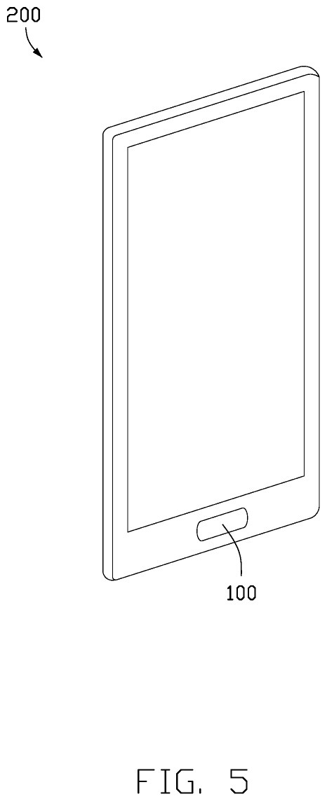

A reinforcing board 23 is mounted on the second rigid portion 202. In at least one embodiment, the reinforcing board 23 and the plurality of electronic components 22 may be mounted on a same surface of the circuit board 20. Referring to FIG. 3, at least one electronic connecting element 24 is mounted on a surface of the second rigid portion 202. Referring to FIGS. 2 and 3, the reinforcing board 23 and the at least one electronic connecting element 24 may be mounted on two opposite surfaces of the second rigid portion 202. When the lens module 100 is installed in an electronic device 200 (shown in FIG. 5), the electronic connecting element 24 is configured to transmit signals between the lens module 100 and other components of the electronic device 200. In at least one embodiment, the electronic connecting element 24 may be a connector or gold fingers.

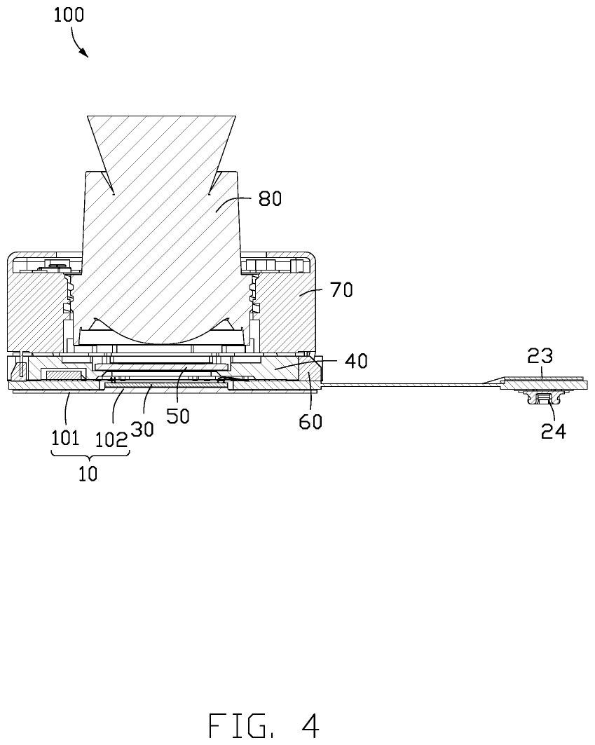

Referring to FIG. 4, the photosensitive chip 30 is mounted on the convex box 102. In at least one embodiment, the photosensitive chip 30 may be rectangular. The photosensitive chip 30 is electrically connected to the circuit board 20 through a wire (not shown), to make the photosensitive chip 30 electrically connected to the electronic component 22.

The base 40 is mounted on the first rigid portion 201. In at least one embodiment, the base 40 may be rectangular. The base 40 includes a second through hole 41 passing through the base 40. The second through hole 41 faces the first through hole 21. That is, the second through hole 41 faces the photosensitive chip 30. The base 40 further includes a groove 42. The base 40 includes a surface 401 away from the circuit board 20, and a portion of the surface 401 surrounding the second through hole 41 is recessed inwardly to form the groove 42. In at least one embodiment, the base 40 may be made of plastic.

The optical filter 50 is received in the groove 42. The optical filter 50 faces the photosensitive chip 30. In at least one embodiment, the optical filter 50 may be rectangular.

The adhesive layer 60 bonds the base 40 to the first rigid portion 201. The adhesive layer 60 improves the binding force between the base 40 and the first rigid portion 201, to enhance the stability between the base 40 and the first rigid portion 201.

The voice coil motor 70 is installed on the surface 401 of base 40 facing away from the circuit board 20. In at least one embodiment, the voice coil motor 70 may be rectangular. The voice coil motor 70 includes a receiving hole 71 passing through the voice coil motor 70. In at least one embodiment, a first thread 711 is formed on the inner surface of the receiving hole 71.

The lens 80 is installed in the receiving hole 71 of the voice coil motor 70. In at least one embodiment, a second thread 81 is formed on an outer surface of the lens 80. The first thread 711 engages with the second thread 81 to fix the lens 80 on the voice coil motor 70.

Referring to FIG. 5, the lens module 100 can be applied in the electronic device 200. The electronic device 200 can be a mobile phone, a laptop, a wearable device, a camera, a monitoring device, or other devices.

In the present disclosure, the metal board 10 includes the convex box 102, and the photosensitive chip 30 is mounted on the convex box 102. Thus, the distance between the photosensitive chip 30 and the lens 80 is reduced. Namely, the back focal length of the lens module 100 can be reduced, which can reduce the total size of the electronic device 200.

In addition, due to a high thermal conductivity of the metal board 10, the heat generated by the photosensitive chip 30 can be dissipated through the metal board 10. Thereby, the heat dissipation efficiency of the lens module 100 can be improved. In addition, the metal board 10 has a high strength, thus improving the strength and reliability of the lens module 100.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A lens module comprising:
a circuit board defining a first through hole;
a metal board comprising a metal body and a convex block on the metal body, the circuit board disposed on the metal board, and the convex block received in the first through hole; and
a photosensitive chip mounted on the convex block.

2. The lens module of claim 1, wherein the lens module further comprises a base and an optical filter, the base is mounted on a surface of the circuit board facing away from the metal board, the base comprises a second through hole, the base further comprises a groove, the base includes a surface away from the circuit board, and a portion of the surface surrounding the second through hole is recessed inwardly to form the groove, and the optical filter is received in the groove.

3. The lens module of claim 2, wherein the lens module further comprises a voice coil motor, and the voice coil motor is installed on a surface of the base facing away from the circuit board.

4. The lens module of claim 3, wherein the voice coil motor comprises a receiving hole, the lens module further comprises a lens, and the lens is installed in the receiving hole.

5. The lens module of claim 4, wherein a first thread is formed on an inner surface of the receiving hole, a second thread is formed on an outer surface of the lens, and the first thread is engaged with the second thread to install the lens in the voice coil motor.

6. The lens module of claim 2, wherein the lens module further comprises an adhesive layer, the adhesive layer bonds the base to the circuit board.

7. The lens module of claim 2, wherein the optical filter faces the photosensitive chip.

8. The lens module of claim 1, wherein the metal board is made of steel.

9. The lens module of claim 1, wherein the circuit board comprises a first rigid portion, a second rigid portion, and a flexible portion connecting between the first rigid portion and the second rigid portion, the lens module further comprises at least one electronic component, the base and the at least one electronic component are mounted on the first rigid portion.

10. An electronic device comprising:
a lens module comprising:
a circuit board defining a first through hole;
a metal board comprising a metal body and a convex block on the metal body, the circuit board disposed on the metal board, and the convex block received in the first through hole; and
a photosensitive chip mounted on the convex block.

11. The electronic device of claim 10, wherein the lens module further comprises a base and an optical filter, the base is mounted on a surface of the circuit board facing away from the metal board, the base comprises a second through hole, the base further comprises a groove, the base includes a surface away from the circuit board, and a portion of the surface surrounding the second through hole is recessed inwardly to form the groove, and the optical filter is received in the groove.

12. The electronic device of claim 11, wherein the lens module further comprises a voice coil motor, and the voice coil motor is installed on a surface of the base facing away from the circuit board.

13. The electronic device of claim 12, wherein the voice coil motor comprises a receiving hole, the lens module further comprises a lens, and the lens is installed in the receiving hole.

14. The electronic device of claim 13, wherein a first thread is formed on an inner surface of the receiving hole, a second thread is formed on an outer surface of the lens, and the first thread is engaged with the second thread to install the lens in the voice coil motor.

15. The electronic device of claim 11, wherein the lens module further comprises an adhesive layer, the adhesive layer bonds the base to the circuit board.

16. The electronic device of claim 11, wherein the optical filter faces the photosensitive chip.

17. The electronic device of claim 10, wherein the metal board is made of steel.

18. The electronic device of claim 10, wherein the circuit board comprises a first rigid portion, a second rigid portion, and a flexible portion connecting between the first rigid portion and the second rigid portion, the lens module further comprises at least one electronic component, the base and the at least one electronic component are mounted on the first rigid portion.
